(19) United States
(12) Patent Application Publication
(10) Pub. No.: US 2024/0379634 A1
(43) Pub. Date: Nov. 14, 2024

(54) STACKED MICRO-DISPLAY STRUCTURE AND MANUFACTURING PROCESS THEREFOR

(71) Applicant: SEMICONDUCTOR INTEGRATED DISPLAY TECHNOLOGY CO., LTD., Wuhu (CN)

(72) Inventors: Xun LV, Wuhu (CN); Shengfang LIU, Wuhu (CN); Wei ZU, Wuhu (CN); Rui XU, Wuhu (CN); Liping YIN, Wuhu (CN)

(21) Appl. No.: 18/660,465

(22) Filed: May 10, 2024

(30) Foreign Application Priority Data
May 12, 2023 (CN) 202310535416.2

(51) Int. Cl. H01L 25/075; H01L 25/16; H01L 33/38; H01L 33/52; H01L 33/62

(52) U.S. Cl. CPC H01L 25/0756; H01L 25/167; H01L 33/38; H01L 33/52; H01L 33/62; H01L 2933/0016; H01L 2933/005; H01L 2933/0066

(57) ABSTRACT

Disclosed in the present disclosure are a stacked micro-display structure and a manufacturing process therefor. The stacked micro-display structure includes a substrate, where a first surface of the substrate is provided with a pixel circuit, and a second surface, opposite to the first surface, of the substrate is provided with a drive circuit. The manufacturing process includes: step 1) preparing a substrate; step 2) manufacturing a drive circuit layer on a back surface, facing upward, of the substrate; step 3) turning the substrate over, and attaching the drive circuit layer to a carrier; step 4) manufacturing a pixel circuit layer on a front surface of the substrate; step 5) manufacturing via holes; step 6) manufacturing interconnects; step 7) manufacturing an anode electrode; and step 8) manufacturing a light-emitting layer and a cathode; and manufacturing an encapsulation layer.

### CROSS-REFERENCE TO RELATED APPLICATIONS

The application claims priority to Chinese Patent Application No. 202310535416.2, filed on May 12, 2023, which is hereby incorporated by reference in its entirety.

### TECHNICAL FIELD

The present disclosure belongs to the technical field of the micro-display, and more particularly, relates to a stacked micro-display structure and a manufacturing process therefor.

### BACKGROUND

A micro-display technology has been widely applied in near-eye display terminal products, including virtual reality (VR), augmented reality (AR), mixed reality (MR), and the like. The micro-display technology includes a micro organic light-emitting diode (Micro OLED), a micro light-emitting diode (Micro LED), a high resolution liquid crystal display (LCD), a liquid crystal on silicon (LCOS), digital light processing (DLP), and the like. As shown in FIGS. 1 and 2, a micro-display chip generally includes two parts, i.e., a pixel circuit and a peripheral drive circuit. The pixel circuits are a repeating pixel circuit array, and are used for driving an optical structure and displaying an image. The peripheral drive circuits include a row driving circuit, a column driving circuit, a memory circuit (static random-access memory, SRAM), a logic operation circuit (logic), an analog-to-digital/digital-to-analog conversion module (ADC/DAC), a control input/output (IO) circuit, a power management module, and the like, and are used for processing and analyzing an input video signal, and output the analyzed video signal to the pixel circuit, so that the pixel circuits display an image. Because a display region of a micro-display itself is large, and the peripheral drive circuit occupies 20-40% of the area, the micro-display chip is typically 0.5-2 inches in size. Under the same process capability, the larger the chip size, the lower the yield. Currently, the micro-display chip is limited by the large chip area, and therefore, the yield is low and the cost is high. At the same time, the larger the chip size, the less dies produced from the same wafer, which will also increase the cost. Due to different working principles of a pixel circuit and a drive circuit of the micro-display, the requirements for a threshold voltage, a threshold current, a leakage current and sub-threshold characteristics of a transistor are different. The pixel circuit requires low electric leakage, high voltage resistance, and the large operating current, so a manufacturing process of 0.3-1 μm is generally used. A driver integrated circuit (IC) requires the faster speed and lower power consumption; and generally, a manufacturing process of 0.18 μm or less is used. The more advanced the manufacturing process, the faster the speed. However, it is difficult to integrate processes with a significant difference on the same wafer at one time due to process differences, for example, processes of 0.5 μm and 0.18 μm can be integrated on the same wafer at one time, but it is difficult to integrate processes of 0.5 μm and 45 nm. The process incompatibility greatly limits the performance improvement of micro-display driver chips. Therefore, it is very meaningful to reduce the chip size, reduce the cost, and develop high-performance micro-display driver chips.

### SUMMARY

An objective of the present disclosure is to solve the problems existing in the prior art, and to provide a stacked micro-display structure with good integrated compatibility, a small area and high yield, and a manufacturing process therefor.

In order to achieve the above objective, the technical solution adopted by the present disclosure is as follows: a stacked micro-display structure is provided, including a substrate, where a first surface of the substrate is provided with a pixel circuit, and a second surface, opposite to the first surface, of the substrate is provided with a drive circuit.

In order to make the above technical solution more detailed and specific, the present disclosure also provides the following further preferred technical solutions to obtain satisfactory practical effects.

The substrate has a sandwich structure and includes an intermediate insulating material layer, and an upper layer and a lower layer of the insulating material layer are both semiconductor material layers.

A pixel circuit layer on the first surface of the substrate and a drive circuit layer on the second surface of the substrate are connected by interconnects.

An anode electrode is disposed on the pixel circuit layer, and a light-emitting layer and a cathode are disposed on the anode electrode.

An encapsulation layer is disposed on the pixel circuit layer.

A carrier is disposed under the drive circuit layer.

A manufacturing process for the stacked micro-display structure includes step 1) preparing a substrate; step 2) manufacturing a drive circuit layer on a second surface, facing upward, of the substrate; step 3) turning the substrate over, and attaching the drive circuit layer to a carrier; step 4) manufacturing a pixel circuit layer on a first surface of the substrate; step 5) manufacturing via holes; step 6) manufacturing interconnects; step 7) manufacturing an anode electrode; and step 8) manufacturing a light-emitting layer and a cathode; and manufacturing an encapsulation layer.

The substrate in the step 1) is a silicon-on-insulator (SOI) wafer.

In the step 3), a first surface of the SOI wafer is thinned.

In the step 6), by using tungsten or copper, and the via holes are filled with the interconnects by using metal deposition and chemical mechanical polishing, to connect a pixel circuit with a drive circuit.

Compared with the prior art, the present disclosure has the following advantages: according to the stacked micro-display structure and the manufacturing process therefor of the present disclosure, the integrated compatibility is good, the area is small, the yield is high, and the cost is low, which has high practicality and better application prospects.

### BRIEF DESCRIPTION OF FIGURES

The contents expressed in the accompanying drawings of this specification and reference signs in the drawings are briefly described below.

FIG. 1 is a schematic structural diagram of a conventional display.

FIG. 2 is a schematic cross-sectional structural diagram of the conventional display.

FIG. 3 is a schematic front structural diagram of a display according to the present disclosure.

FIG. 4 is a schematic back structural diagram of a display according to the present disclosure.

FIG. 5 is a schematic cross-sectional structural diagram of a display according to the present disclosure.

FIG. 6 is a schematic structural diagram of a stacked display according to the present disclosure.

FIG. 7 shows (1)-(2) in a process flowchart of a stacked display according to the present disclosure.

FIG. 8 shows (3)-(4) in the process flowchart of the stacked display according to the present disclosure.

FIG. 9 shows (5)-(6) in the process flowchart of the stacked display according to the present disclosure.

FIG. 10 shows (7)-(8) in the process flowchart of the stacked display according to the present disclosure.

FIG. 11 is a schematic diagram of conductive connection of the display according to the present disclosure.

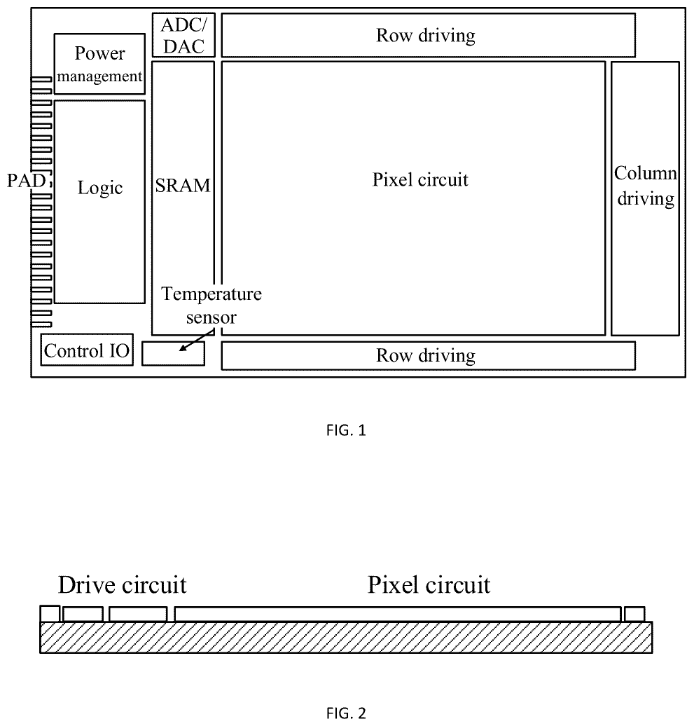

### DETAILED DESCRIPTION

Specific implementation modes of the present disclosure will be further described below in detail by describing the embodiments with reference to the accompanying drawings.

In the description of the present disclosure, it should be noted that the orientation or position relationship indicated by the terms such as “upper”, “lower”, “front”, “rear”, “left”, “right”, “vertical”, “inner”, “outer” and the like is based on the orientation or position relationship shown in the drawings. The terms are only for the convenience of describing the present disclosure and simplifying the description, rather than indicating or implying that the device or element referred to must have a specific orientation and be constructed and operated in a specific orientation, and therefore cannot be understood as a limitation of the present disclosure.

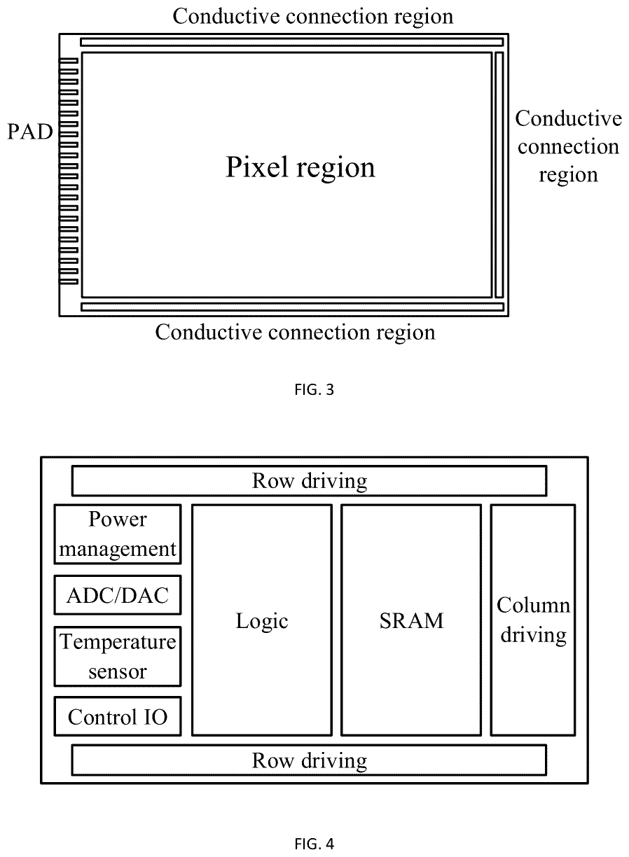

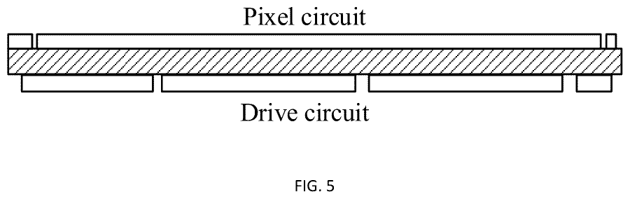

The stacked micro-display structure of the present disclosure, as shown in FIGS. 3, 4 and 5, includes a substrate; and a first surface of the substrate is provided with pixel circuits, and a second surface of the substrate is provided with drive circuits. In the embodiments, the first surface is a front surface, and the second surface is a back surface opposite to the first surface. Conductive connection regions are disposed at edges of a pixel region. In the present disclosure, the pixel circuits are manufactured on the first surface of the substrate and the drive circuits are manufactured on the second surface of the substrate, so that the chip area can be reduced, the yield is improved, and the problems of high cost and poor performance of the micro-display are solved. Meanwhile, the pixel circuit and the drive circuit are separately manufactured, which is convenient to be compatible with different manufacturing process requirements, to simultaneously satisfy the demands of low electric leakage, high voltage resistance and the large operating current of the pixel circuits, and the demands of high speed and low power consumption of the drive circuits, thereby manufacturing a high-performance micro-display chip.

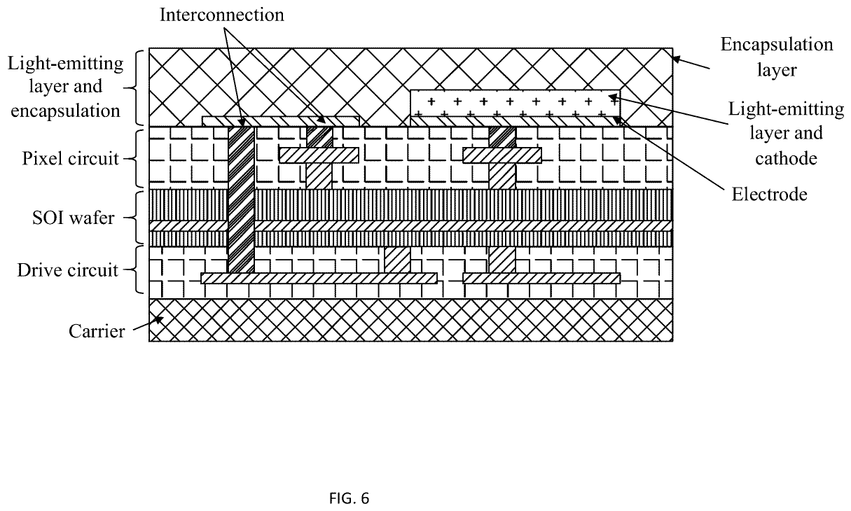

In the present disclosure, as shown in FIG. 6, the substrate of the stacked micro-display structure is a silicon-on-insulator (SOI) wafer, and has a sandwich structure including an intermediate insulating material layer; and an upper layer and a lower layer of the insulating material layer are both semiconductor material layers. The insulating material layer may be a layer structure made of any one of insulating materials such as silicon oxide, silicon nitride, silicon oxynitride, and aluminum oxide. Each semiconductor material layer may also be a layer structure made of any one of materials such as monocrystalline silicon, polycrystalline silicon, indium gallium zinc oxide (IGZO), indium zinc oxide (IZO), GaN, GaAs, and SiC. A pixel circuit layer on a front surface of the SOI wafer and a drive circuit layer on a back surface of the SOI wafer are connected by interconnects. An anode electrode is disposed on the pixel circuit layer, and a light-emitting layer and a cathode are disposed on the anode electrode; and an encapsulation layer is disposed on the pixel circuit layer. A carrier is disposed under the drive circuit layer.

According to the stacked micro-display structure of the present disclosure, the chip area can be reduced by 20-40% and the yield can be improved by 20%-50% by developing a stacked architecture on the SOI wafer and respectively manufacturing the drive circuits and the pixel circuits on the back surface and the front surface of the substrate. At the same time, the number of chips produced by one wafer is increased by 20%-60%, and the overall cost is reduced by 30%-60%, which solves the problems of high cost and poor performance of a micro-display. Meanwhile, the pixel circuit and the drive circuit are separately manufactured, which is convenient to be compatible with different manufacturing process requirements, for example, the pixel circuit uses a process of 0.5 μm, and the peripheral drive circuit uses a process of 45 nm, to simultaneously satisfy the demands of low electric leakage, high voltage resistance and the large operating current of the pixel circuits, and the demands of high speed and low power consumption of the drive circuits, thereby manufacturing a high-performance micro-display chip. The present disclosure belongs to the display industry, particularly the field of the micro-display, and the stacked micro-display structure can be used in a Micro OLED, a Micro LED, an LCOS, a DLP, and a high resolution liquid crystal display (LCD), etc.

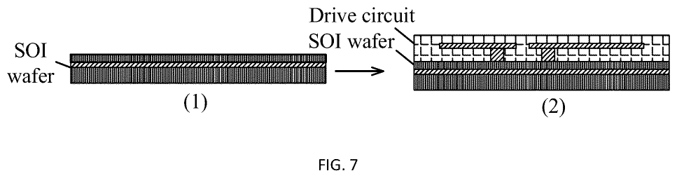

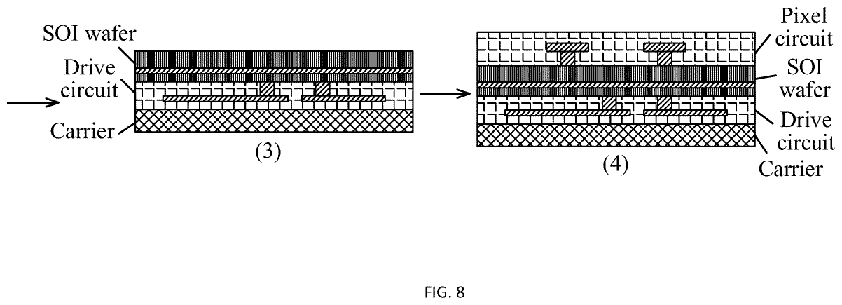

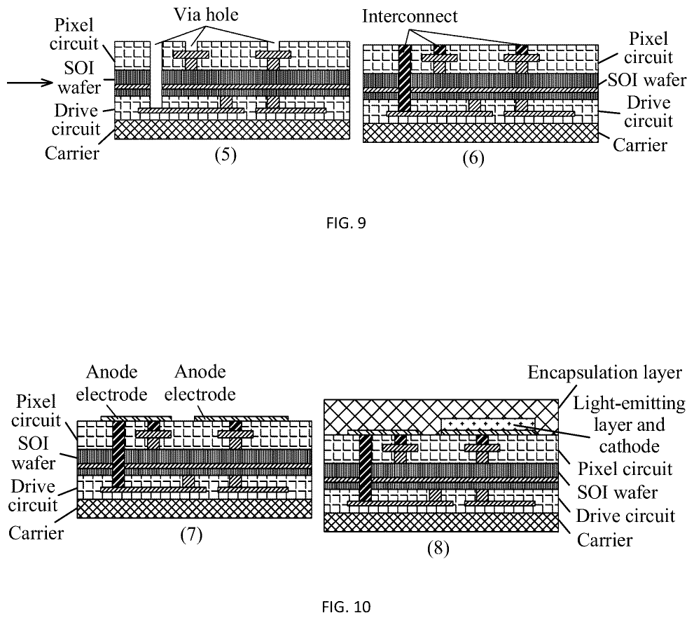

The present disclosure provides a manufacturing process for the stacked micro-display structure, as shown in FIGS. 7-10, including step 1) preparing a substrate; step 2) manufacturing a drive circuit layer on a second surface, facing upward, of the substrate; step 3) turning the substrate over, and attaching the drive circuit layer to a carrier; step 4) manufacturing a pixel circuit layer on a first surface of the substrate; step 5) manufacturing via holes; step 6) manufacturing interconnects; step 7) manufacturing an anode electrode; and step 8) manufacturing a light-emitting layer and a cathode; and manufacturing an encapsulation layer.

In the step 1), the substrate is an SOI wafer.

In the step 3), a front surface of the SOI wafer is thinned.

In the step 6), by using tungsten or copper, the via holes are filled with the interconnects by using metal deposition and chemical mechanical polishing, to connect a pixel circuit with a drive circuit.

The present disclosure relates to a manufacturing process for the stacked micro-display structure, in particular as follows.

Step 1) a substrate is prepared, here, the substrate is an SOI wafer and has a sandwich structure, an upper layer and a lower layer are both monocrystalline silicon which can be used for manufacturing transistors, and an intermediate layer silicon oxide.

Step 2) a drive circuit layer is manufactured on a back surface, facing upward, of the SOI wafer. According to the demands of high speed and low power consumption of drive circuits, advanced processes such as 28 nm, 45 nm, 65 nm, and 90 nm can be selected.

Step 3) the SOI Wafer is turned over, and the drive circuit layer is attached to a carrier, where the carrier can be selected from a silicon wafer, a glass sheet, and the like; and a first surface of the SOI Wafer is thinned, which is beneficial for interconnection of the pixel circuit and the drive circuit. The wafer can be thinned to 50-500 μm.

Step 4) a pixel circuit layer is manufactured on a front surface of the SOI wafer. According to the demands of low electric leakage, high voltage resistance, and the large operating current of pixel circuits, processes with a large line width of 1 μm, 0.5 μm, 0.35 μm and the like can be selected.

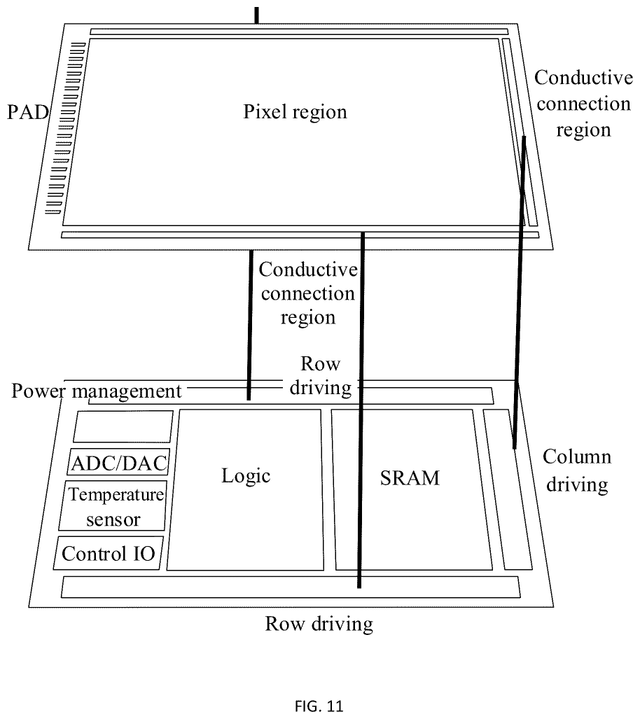

Step 5) via holes are manufactured. A manufacturing method is as shown in step 5 of a process flowchart in FIG. 9, desired holes are photoetched in conductive connection regions, the holes are etched into the drive circuit layer, and the photoresist is removed. FIG. 11 is a schematic diagram of conductive connection.

Step 6) interconnects are manufactured to connect the pixel circuit with the drive circuit, where the pixel circuit is connected with the drive circuit by metal deposition and chemical mechanical polishing by using tungsten or copper.

Step 7) an anode electrode is manufactured, namely the anode electrode is manufactured on the pixel circuit. The anode electrode is connected to and in contact with the interconnects, and the electrode serves as an electrode required for the pixel region and simultaneously serves as a metal for interconnection of the pixel circuit and the drive circuit. Processes of metal deposition, photoetching, and etching are used. The electrode serves as the electrode required for the pixel region and simultaneously serves as the metal for interconnection of the pixel circuit and the drive circuit. The anode electrode is located in the pixel region and on the periphery of the drive circuit.

Step 8) a light-emitting layer and a cathode are manufactured, namely the light-emitting layer and the cathode are evaporated in sequence in the pixel region. The light-emitting layer and the cathode are located in the same position. The light-emitting layer is sandwiched between the cathode and the anode, and when the anode and the cathode are energized, the light-emitting layer emits light. Different products have different manufacturing processes. The Micro OLED uses evaporation and other processes; the Micro LED uses mass transfer printing, lamination and other processes; the LCOS uses liquid crystals and other processes; and microlenses are manufactured for DLP. An encapsulation layer is manufactured.

In the present disclosure, the chip area can be reduced by 20-40%, the requirements of micro-displays are met, and the yield can be improved by 20%-50% by developing a stacked architecture on the SOI wafer and respectively manufacturing the drive circuits and the pixel circuits on the back surface and the front surface of the silicon wafer. At the same time, the number of chips produced by one wafer is increased by 20%-60%, and the overall cost is reduced by 30%-60%, which solves the problems of high cost and poor performance of a micro-display. Meanwhile, the pixel circuits and the drive circuits are separately manufactured, which is convenient to be compatible with different manufacturing process requirements, to simultaneously satisfy the demands of low electric leakage, high voltage resistance and the large operating current of the pixel circuits, and the demands of high speed and low power consumption of the drive circuits, thereby manufacturing a high-performance micro-display chip.

According to the stacked micro-display structure and the manufacturing process therefor of the present disclosure, the integrated compatibility is good, the area is small, the yield is high, and the cost is low, which has high practicality and better application prospects.

In the description of the present disclosure, it should be noted that the terms “mounted”, “connected” and “connection” should be understood in a broad sense unless otherwise specified and defined. For example, it can be fixed connection, detachable connection or integrated connection; it can be mechanical connection or electrical connection; and it can be direct connection or indirect connection through intermediate media. Those of ordinary skill in the art may understand the specific meanings of the above terms in the present disclosure according to specific situations.

Hereto, the technical solutions of the present disclosure have been described in connection with the preferred implementations shown in the accompanying drawings. However, it is easily understood by those skilled in the art that the protection scope of the present disclosure is obviously not limited to these specific implementations. Those skilled in the art can make equivalent changes or replacements to the relevant technical features without departing from the principle of the present disclosure, and the technical solutions after these changes or replacements will all fall within the protection scope of the present disclosure.

The above are only the preferred embodiments of the present disclosure, and are not intended to limit the present disclosure; and various modifications and variations of the present disclosure may be made for those skilled in the art. Any modifications, equivalent replacements, improvements and the like made without departing from the spirit and scope of the present disclosure should fall within the scope of protection of the present disclosure.

What is claimed is:

1. A stacked micro-display structure, comprising: a substrate;
wherein a first surface of the substrate is provided with a pixel circuit; and
a second surface, opposite to the first surface, of the substrate is provided with a drive circuit.

2. The stacked micro-display structure according to claim 1, wherein the substrate has a sandwich structure and comprises an intermediate insulating material layer; and
an upper layer and a lower layer of the insulating material layer are both semiconductor material layers.

3. The stacked micro-display structure according to claim 1, wherein a pixel circuit layer on the first surface of the substrate and a drive circuit layer on the second surface of the substrate are connected by interconnects.

4. The stacked micro-display structure according to claim 3, wherein an anode electrode is on the pixel circuit layer, and a light-emitting layer and a cathode are on the anode electrode.

5. The stacked micro-display structure according to claim 4, wherein an encapsulation layer is on the pixel circuit layer.

6. The stacked micro-display structure according to claim 5, wherein a carrier is disposed under the drive circuit layer.

7. A manufacturing process for the stacked micro-display structure according to claim 1, comprising:
step 1) preparing the substrate;
step 2) manufacturing a drive circuit layer on the second surface, facing upward, of the substrate;
step 3) turning the substrate over, and attaching the drive circuit layer to a carrier;
step 4) manufacturing a pixel circuit layer on the first surface of the substrate;
step 5) manufacturing via holes;
step 6) manufacturing interconnects;
step 7) manufacturing an anode electrode; and
step 8) manufacturing a light-emitting layer and a cathode; and manufacturing an encapsulation layer.

8. The manufacturing process for the stacked micro-display structure according to claim 7, wherein the substrate in the step 1) is a silicon-on-insulator (SOI) wafer.

9. The manufacturing process for the stacked micro-display structure according to claim 8, further comprising: in the step 3), thinning the first surface of the SOI Wafer.

10. The manufacturing process for the stacked micro-display structure according to claim 7, further comprising: in the step 6), by using tungsten or copper, filling the via holes with the interconnects by using metal deposition and chemical mechanical polishing, to connect the pixel circuit with the drive circuit.
